(19) United States
(12) Patent Application Publication
(10) Pub. No.: US 2025/0079358 A1
(43) Pub. Date: Mar. 6, 2025

(54) METHODS OF ELECTRONIC SYSTEM ASSEMBLY WITH THERMAL INTERFACE PAD AND RELATED ASSEMBLIES

(71) Applicant: Tesla, Inc., Austin, TX (US)

(72) Inventors: Abel Misrak, Redwood City, CA (US); Mohamed Nasr, Sunnyvale, CA (US); Aydin Nabovati, Toronto (CA); Rishabh Bhandari, San Carlos, CA (US)

(21) Appl. No.: 18/727,867

(22) PCT Filed: Jan. 10, 2023
(86) PCT No.: PCT/US2023/010458

§ 371 Date: Jul. 10, 2024

Related U.S. Application Data
(60) Provisional application No. 63/299,670, filed on Jan. 14, 2022.

(51) Int. Cl. H01L 23/00; H01L 23/473; H01L 23/498; H01L 25/065

(52) U.S. Cl. CPC H01L 24/05; H01L 23/473; H01L 23/49811; H01L 24/08; H01L 24/80; H01L 25/0657; H01L 2224/05015; H01L 2224/08054; H01L 2224/08145; H01L 2224/80091; H01L 2225/06589; H01L 2924/1427

(57) ABSTRACT

Aspects of this disclosure relate to a method of assembly that includes thermally coupling two components. The method includes providing a thermal interface pad between the two components, such as an integrated circuit and a cooling solution. The thermal interface pad can have a star shape, and a pressure is applied to at least one of the two components. The pressure can cause the star shape thermal interface to expand into a rectangular shape. The expanded rectangular shape does not expand into keep out area positioned around an electronic component of the two components.

### CROSS-REFERENCE TO RELATED APPLICATION

This application is a non-provisional of and claims priority to U.S. Provisional Patent Application No. 63/299,670, entitled “SYSTEMS AND METHODS OF MANUFACTURE WITH THERMAL INTERFACE PAD,” filed on Jan. 14, 2022, which is hereby incorporated by reference in its entirety and for all purposes.

### BACKGROUND

### TECHNICAL FIELD

The disclosed technology relates to a thermal interface pad for an electronic system assembly process. More specifically, the disclosed technology relates to an electronic assembly system and the method for assembling the electronic system with a compressible thermal interface pad that is rectangular after assembly.

### DESCRIPTION OF RELATED TECHNOLOGY

In an integrated circuit (IC) chip assembly on a cooling solution where multiple IC chips are assembled on the cooling solution, each IC chip can have a rectangular shape. During a normal operation of the IC chips, heat is generated. The heat causes the IC chip's temperature to increase. Thus, a reduction of the IC chip temperature is desirable to operate the chip within its operating temperature range. There are technical challenges related to the thermal interfaces of the IC chips.

### SUMMARY

The innovations described in the claims each have several aspects, no single one of which is solely responsible for its desirable attributes. Without limiting the scope of the claims, some prominent features of this disclosure will now be briefly described.

One aspect of this disclosure is a method of thermally coupling components in an integrated circuit (IC) assembly. The method includes providing a thermal interface pad between two components in an IC assembly and applying pressure to at least one of the two components of the IC assembly to thermally couple the two components by way of the thermal interface pad The thermal interface pad has a star shape with a plurality of points. Applying the pressure expands the thermal interface pad and changes a shape of the thermal interface pad from the star shape to another shape.

In the method of thermally coupling components in an integrated circuit assembly, the star shape of the thermal interface pad can be a four-point star shape.

In the method of thermally coupling components in an integrated circuit assembly, the shape of the thermal interface pad can be a rectangular shape after the applying pressure.

In the method of thermally coupling components in an integrated circuit assembly, the two components can include an integrated circuit chip and a cooling solution. The thermal interface pad can be expanded outside of a keep out area around connectors after applying the pressure. The connectors can be positioned around the integrated circuit chip. In certain applications, the connectors can include pogo pins.

In the method of thermally coupling components in an integrated circuit assembly, the integrated circuit chip can be a voltage regulating module.

The method of thermally coupling components in an integrated circuit assembly can further include compressing a plurality of additional star shaped thermal interface pads positioned between respective additional integrated circuit chips and the cooling solution.

Another aspect of this disclosure is a method of thermally coupling components in an integrated circuit (IC) assembly, including providing a thermal interface pad between two components in an IC assembly and applying pressure to at least one of the two components of the IC assembly. Applying pressure thermally couples the two components by way of the thermal interface pad. Applying pressure expands the thermal interface pad and changes a shape of the thermal interface pad from a first shape to a rectangular shape. The thermal interface pad is spaced apart from a connector interface for connecting to one of the two components after applying the pressure.

In the method of thermally coupling components in an integrated circuit assembly, the first shape can be a star shape. The star shape can be a four point star shape. The first shape can be symmetric.

In the method of thermally coupling components in an integrated circuit assembly, the rectangular shape of the thermal interface pad can be expanded outside of keep out areas around connector areas after applying the pressure. The connector areas can be positioned around one of the two components or both components. In certain applications, the connector areas can include a plurality of pogo pins.

In the method of thermally coupling components in an integrated circuit assembly, the two components can include an integrated circuit chip and a cooling solution.

In the method of thermally coupling components in an integrated circuit assembly, the integrated circuit chip can be a voltage regulating module.

Another aspect of this disclosure is an electronic assembly made by a process. The process includes providing a thermal interface pad between an integrated circuit chip and a cooling solution and applying pressure so as to thermally couple the integrated circuit chip to the cooling solution by way of the thermal interface pad. The thermal interface pad has a star shape with a plurality of points. Applying the pressure expands the thermal interface pad and changes the shape of the thermal interface pad from the star shape to a rectangular shape.

The electronic assembly can include connector interfaces around the integrated circuit chip. The thermal interface pad can be positioned outside of keep out regions around the connector interfaces after applying the pressure.

The integrated circuit chip in the electronic assembly can include a voltage regulating module.

The cooling solution in the electronic assembly can include a cold plate.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Embodiments of this disclosure will be described, by way of non-limiting example, with reference to the accompanying drawings.

FIG. 1A is a schematic diagram of an IC chip on a cooling solution.

FIG. 1B is a flow diagram of an IC chip assembly process.

FIG. 2A is a schematic diagram of a traditional IC chip assembly with a rectangular thermal interface pad before a compression process.

FIG. 2B is a schematic diagram of a traditional IC chip assembly with a rectangular thermal interface pad after a compression process.

FIG. 2C is a schematic diagram of a close-up view of an assembled IC chip of FIG. 2B.

FIG. 3 is a schematic diagram of star shape thermal interface pads on a cooling solution.

FIG. 4 is a schematic diagram of a star shape thermal interface pad.

FIG. 5 is a schematic a cross-sectional view of embodiments of an IC chip assembly that includes thermal interface pads.

FIG. 6 is a schematic diagram that illustrates the thermal interface pad and its expansion due to a compression.

FIG. 7 is a schematic diagram of an array of IC chips, mounted onto thermal interface pads before a compression process.

FIG. 8 is a schematic diagram of an array of IC chips after the thermal interface pads are compressed.

FIGS. 9A-9D are schematic diagrams of various embodiments of the thermal interface pad.

FIGS. 10A-10D depict example embodiments of the thermal interface pad before and after compression.

### DETAILED DESCRIPTION

The following detailed description of certain embodiments presents various descriptions of specific embodiments. However, the innovations described herein can be embodied in a multitude of different ways, for example, as defined and covered by the claims.

This description makes reference to the drawings where reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings.

In an electronics assembly, one or more integrated circuit (IC) chips and neighboring components, such as connectors and/or other electrical components, can be assembled on a cooling solution, and a thermal interface material (TIM) is positioned between the IC chip and the cooling solution. The TIM can function as a heat transfer medium so that the heat generated from the IC chip can be transferred through the TIM to the cooling solution. The cooling solution can be, for example, a heat sink, heat spreader, cold plate, etc., and the disclosed technology is not limit the type of cooling solution. The neighboring component can include but is not limited to connectors that function as an electrical connection interface for an IC chip. The neighboring component can be any suitable electronic component located in proximity with at least one IC chip. For example, the electronic component can be a voltage regulator, a switch, a memory, a processor, a storage device, etc. The neighboring component may include a plurality of connectors that connect an IC chip to another component, such as an IC chip or an external device. In certain IC chip assemblies on a cooling solution, an IC chip is rectangular and surrounded by connector interfaces. The connector interfaces can be pogo pin interfaces, for example. A pogo pin is a spring loaded pin that provides an electrical connection. Each side of the IC chip can be electrically connected to the corresponding pin interface.

The IC chip generates heat during normal IC chip operation, where power is applied to the IC chip. Reducing IC chip temperature can facilitate the IC chip operating within an operational temperature range. A mechanism for reducing the IC chip's temperature during operation can be produced during the IC chip assembly process. For example, a TIM can be included between an IC Chip and a cooling solution. The TIM is a thermally conductive material and can be selected based on its thermal conductivity and application. The TIM has different forms. One common form of TIM that is applied on an electronic device is a thermal interface pad (TIP).

The TIP application on an IC chip during an IC chip and cooling solution assembly process can encounter technical challenges, such as the TIP expanding to a keep out area around the electronics components and interfering with neighboring components. The TIP is a type of TIM that can be either electrically non-conductive material or electrically conductive material. TIPs disclosed herein can include compressible TIM. For example, the TIP is placed between two components, such as the cooling solution and IC chip, and compressed during the assembly process by applying pressure onto at least two components. Applying the pressure can result in compressing the TIP, and the TIP can expand and change shape with the compression. The TIP's expansion to the keep out area can cause a pin interface failure by either insulating the interfaces and preventing proper electrical contact or by causing short between exposed electrical components. For example, the TIP's expansion into the keep out area may cause electrical and/or mechanical interference in the neighboring component by shorting the one or more of the connectors within the neighboring components, deformation of the connectors interface, etc.

The TIP should mostly or fully cover top side of each IC chip to effectively reduce the IC chip temperature during its operation. However, a compressible TIP with a rectangular shape prior to expansion can be compressed into a non-uniform shape during the assembly of the cooling solution. One mitigation to avoid expansion of the TIM into the keep-out areas is to undersize the TIP to an area smaller than the area of the target IC chip. In such cases, the post assembly shape (e.g., shape after compressing the TIP during the assembly process) may not fully cover the area of the IC chip and impact the thermal performance while it remains clear from the keep out area due. However, certain pre-compression rectangular shaped TIPs that ensure the full coverage of the IC chip area post compression can causes the compressed TIP to extrude into the keep out areas. This can cause electrical problems. Furthermore, to prevent the TIP from extending into the keep out areas, the traditional assembly can involve covering less IC area than desired with a TIP.

During an assembly process, the TIP can be placed onto a cooling solution. Then, an IC chip can be placed onto the TIP, and the TIP is compressed to assemble the IC chip onto the cooling solution. To effectively cover the entire area underneath the IC chip, it can be desirable for the TIP to expand to a rectangular shape corresponding to the IC chip post assembly However, certain pre-compression rectangular TIPs expand into a circular shape after compression. The expanded circular shape TIP can be problematic when the TIP expands to the keep out area around the IC chip. If the TIP is expanded to the keep out area, the TIP can cause issues related to the reliability of the neighboring connections. TIM expansion beyond the keep out area can also cause functionality issues at startup. In some instances, a neighboring pin connection failure can result from a TIP expanding into a keep out region. In some instances, if the TIP is electrically conductive, the expansion of the TIP post-compression into the keep areas can cause electrical damage. Furthermore, the expanded circular shape TIP may not fully cover the area under the IC chip. This can affect the overall thermal performance and increase the chip temperature during its operation.

Embodiments of this disclosure relate to shaping a TIP to obtain desirable coverage of an integrated circuit area after assembly while keeping the TIP outside of a keep out area around pins. A TIP is a type of thermal interface material (TIM). In embodiments, the TIP's shape is enhanced and/or optimized to effectively cover the entire area under the IC chip. At the same time, the TIP can remain outside of a keep out area around neighboring components after the TIP is compressed. Thus, by applying certain TIP shapes, the TIP can covers most or the entire area under an IC chip while avoiding expansion of the TIP to a keep out area around neighboring components.

In some embodiments, a plurality of IC chips and neighboring components are assembled onto a cooling solution. In these embodiments, each IC chip is connected to corresponding neighboring components. The connection can be any suitable electrical connection, such as an electrical wire connection or a via the connection. The IC chip can be any chip component that includes any suitable integrated circuits such as a voltage regulator module, microcontroller, power amplifier, or any controller area network (CAN) communication circuit. The cooling solution can be a cold plate or any suitable cooling solution.

In some embodiments, each IC chip is mounted onto the cooling solution surrounded by four pin areas. In these embodiments, each pin area is an interface comprising one or more pins. The pins can be pogo pins, for example. Each pin can electrically connect one or more IC chips. The pins can alternatively additionally be connected to an external device.

In some embodiments, a TIP is positioned onto a cooling solution, where an IC chip is mounted. The TIP can include TIM that has a shape comprising a star with a plurality of points. The star shape can have at least 4 points in certain applications. The sides of the star shape can have straight lines or curved lines The star shape can have sharp points and/or rounded points. The TIP can have a star polygon shape, a convex polygon shape having three sides, a convex polygon shape having five or more sides, diamond shape, rectangular shape with curved lines, or the like prior to expansion. The TIP can have a symmetric shape prior to expansion in certain applications. After pressure is applied to the TIP, the TIP can expand and change shape to a rectangular shape. In certain applications, the TIP can be star shaped and have 6 points prior to expansion, and the TIP changes its shape to a hexagon shape after expansion. Any suitable number of points and length of each point from the center of the star shape can be used as the thermal interface pad. The number of points and length of each point from the center of the star shape can be determined based at least on one or more of the thickness of the thermal interface material, types or material of the cooling solution, or size of the electronic component or IC chip.

In some embodiments, an IC chip is mounted onto a TIP by applying pressure, which compresses the TIP. In these embodiments, the TIP is expanded due to the compression. The compressed thickness is determined based on the TIM, cooling solutions, applied pressure, or IC chip size.

In some embodiments, the TIP has a four-point star shape. Certain four-point star shapes of the TIP can optimize the operation of the IC chip. The position of each point and the size of the four-point star shape of the TIP may be determined based on the initial thickness and compressed thickness of the TIP.

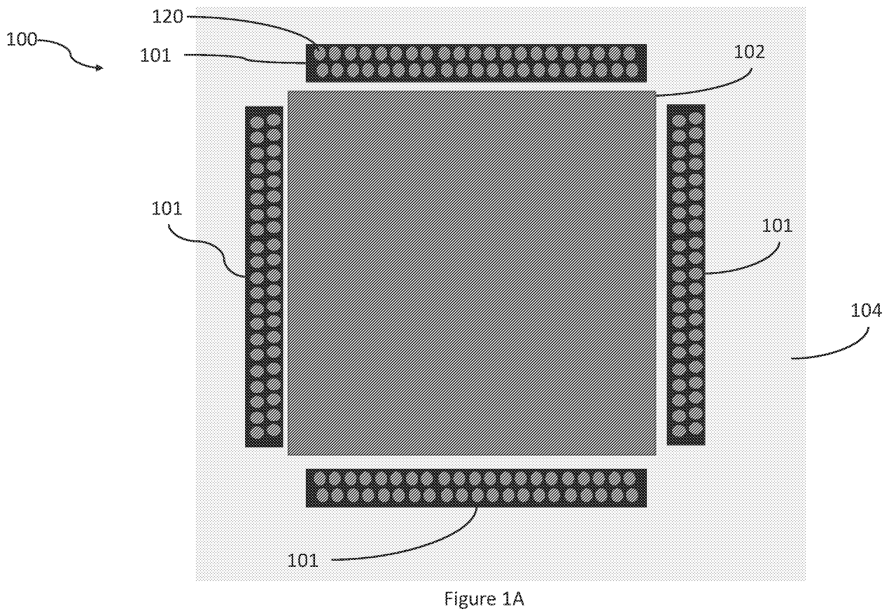

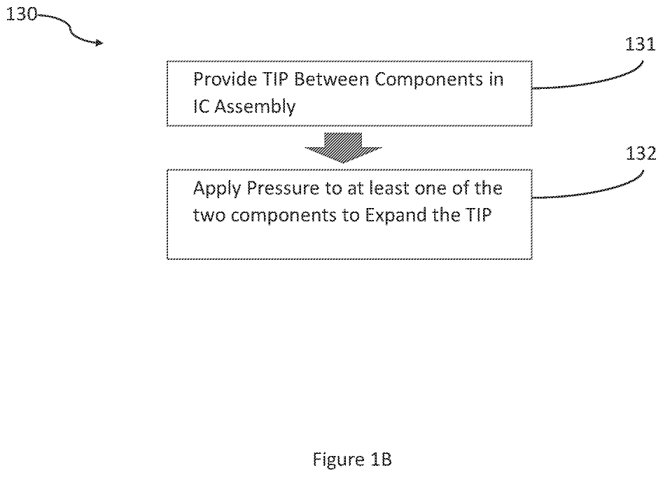

FIG. 1A depicts an IC chip 102 on a cooling solution 104. The cooling solution 104 can be, for example, a heat sink, heat spreader, cold plate, etc. As shown in FIG. 1A,, the IC chip 102 can be surrounded by neighboring pin interfaces 101. The pin interfaces 101 are examples of connector interfaces for providing electrical connections with the IC chip 102. The neighboring pin interfaces 101 can include pins 120 and function as an electrical connection interface for an IC chip 102. A neighboring component, such as a voltage regulator, a switch, a memory, a processor, a storage device, etc, can be electrically connected with the IC chip 102 via the pins 120 included in the neighboring electrical component interface 101. In some embodiments, the pins 120 can be pogo pins. In some embodiments, any suitable electronic component can be electrically connected to the IC chip 102 via one or more of the pins 120. In some embodiments, one or more neighboring pin interfaces 101 are electrically connected to the IC chip 102. The electrical connection (not shown in FIG. 1A) can include any suitable electrical connection, such as electrical bonding, electrical wire connection, or via the connection. In some embodiments, the neighboring pin interface 101 is an electric interface of the IC chip 102. The neighboring pin interface 101 can include any suitable pins, such as pogo pins, complaint connectors, or any other suitable pins. In some embodiments, the neighboring pin interface 101 can connect to one or more IC chips 102. Thus, an IC chip 102 can transmit or receive a signal to or from other IC chips 102 by way of the neighboring pin interface 101. In one embodiment, the neighboring pin interface 101 is connected to one or more external devices, enabling an IC chip 102 to electrically connect to an external device. In some embodiments, the IC chip 102 is connected to an external power source. In this embodiment, the IC chip 102 receives power through the neighboring pin interface 101. These neighboring pin interfaces can be the keep out areas, so any material that can block, reflect, or distort the power and/or signals are kept out from these neighboring pin interface areas.

During normal operation of the IC chip 102, the IC chip 102 generates heat that increases the temperature of the IC chip 102. In some embodiments, a TIP in accordance with any suitable principles and advantages disclosed herein is positioned between the cooling solution 104 and IC chip 102 to reduce the increase in IC chip 102 temperature. The TIP is a type of a TIM which may be selected based on its thermal conductivity and mechanical property such as hardness. The IC chip 102 can include any suitable IC chip. As an example, the IC chip 102 can be a voltage regulating module. The cooling solution 104 can be a cooling solution, such as a cold plate.

FIG. 1B is a flow diagram of an IC chip assembly process 130. The assembly process 130 can apply and expand a TIP between an IC chip 102 and a cooling solution 104 of FIG. 1A and/or any suitable embodiment disclosed herein. In one embodiment, as shown in FIG. 1B, a TIP can be provided between two components at block 131. The two components can include a cooling solution and an integrated circuit. For instance, the TIP can be provided between a cold plate and a voltage regulating module. The TIP can be applied to the cooling solution and then the integrated circuit can be positioned over the TIP in certain applications. The IC and the TIP can be included between neighboring pin interfaces 101 of the cooling solution.

Pressure is applied and the TIP is compressed to thermally couple the components and cause the TIP to expand at block 132. The compression can change the shape of the TIP. For example, a star shaped TIP with four points can change to a rectangular shape due to the compression. The process 130 can be applied to including TIPs as thermal interfaces between respective ICs of an array of ICs and a cooling solution. The star shaped TIP at block 131 is compressed at block 132, expanding the shape into a rectangular shape. The expanded TIPs can have a smaller thickness that the TIPs before expansion.

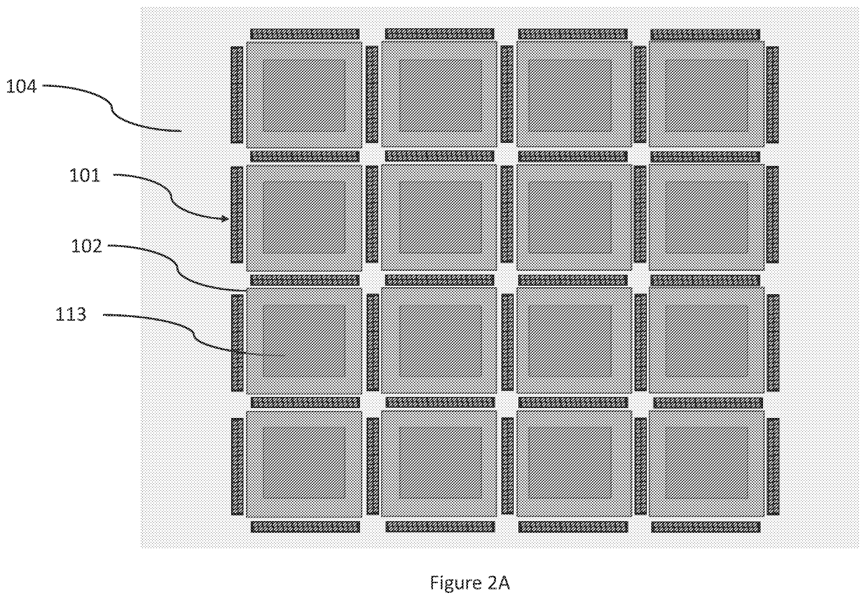

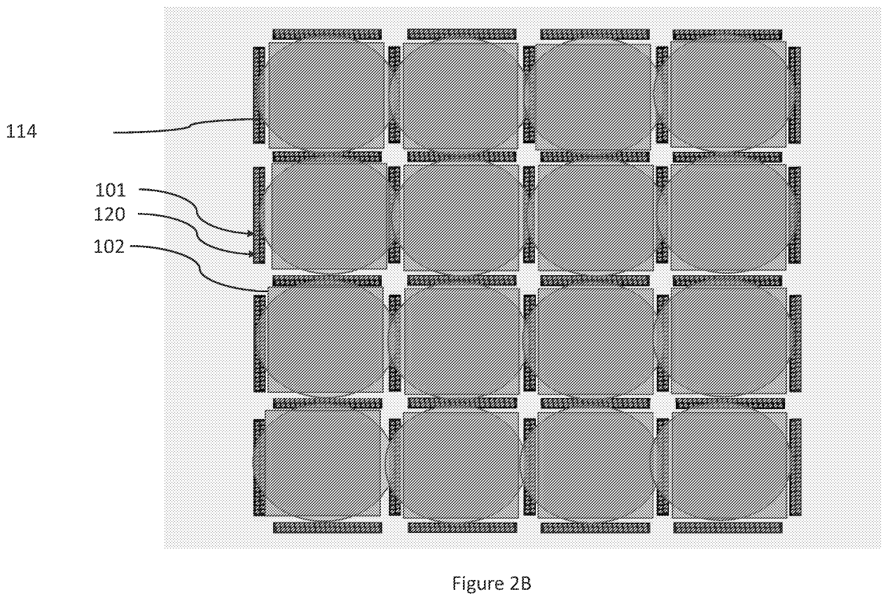

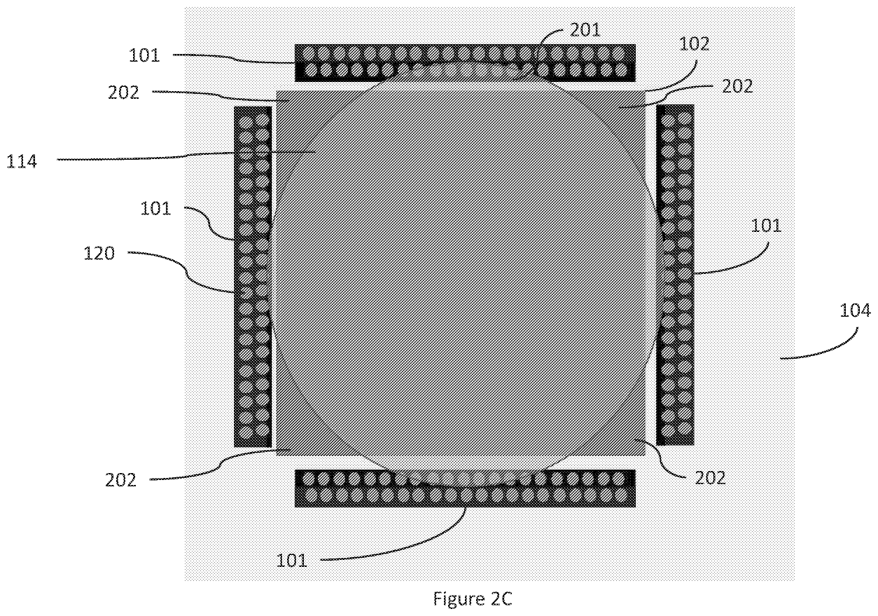

The expanded TIPs created by this process can have physical differences from TIPs formed by other processes. The expanded TIPs can be compressible TIPs that expand through application of pressure during manufacture into a rectangular shape. Other compressible TIPs that start as rectangular shapes can expand to be circular, for example, as shown in FIG. 2B. Moreover, expanded TIPs formed by the process 130 are made of compressible TIM, unlike stiffer TIPs that do not compress and expand during manufacture.

FIGS. 2A-2C illustrate a traditional IC assembly with thermal interface pads (TIP). As shown in FIGS. 2A-2C, traditionally, the TIP initially has a rectangular shape, and the TIP is expanded into a circular shape during the IC assembly process. In this traditional IC assembly, the expanded circular shape TIP may cover parts of the neighboring pin interface 101. This can cause electrical and/or mechanical interference in the neighboring component by shorting the one or more of the connectors within the neighboring components, deformation of the connectors interface, etc.

FIG. 2A illustrates an IC chip assembly before a compression process. In this IC assembly, TIPs 113 are positioned between respective IC chips 102 and the cooling solution 104. As shown in FIG. 2A, the TIPs 113 have a rectangular shape prior to compression. Each rectangular shape TIP 113 is located between an IC chip 102 and the cooling solution 104. During the IC assembly process, pressure is applied to cause the TIP 113 to be compressed.

FIG. 2B illustrates the IC assembly of FIG. 2A after a compression process. When the rectangular TIP 113 is compressed, the rectangular TIP 113 is expanded into a circular shape TIP 114. FIG. 2C depicts a close-up view of an IC chip assembly in FIG. 2B after the TIP 114 compression. As shown in FIG. 2C, the circular TIP 114 covers part of the neighboring pin interface 101. Since the TIP is an electrically non-conductive material, the TIP insulates the covered neighboring pin interface area 201. Thus, electrical connections associated with the covered pogo pins 120 can be unreliable. Furthermore, the area under the IC chip 102 that is not covered by the expanded TIP 114 (area 202 as shown in FIG. 2C) can increase the IC chip 102 temperature during its operation.

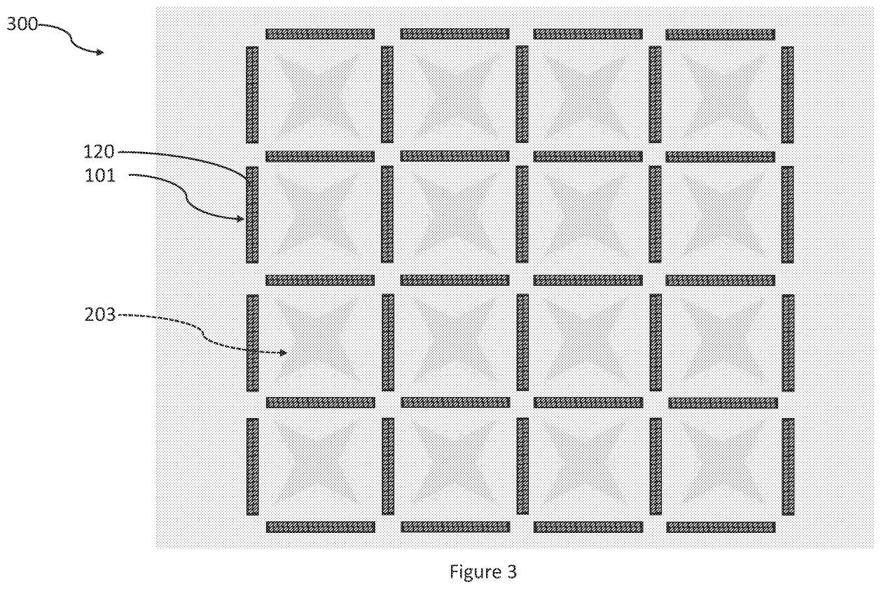

FIG. 3 depicts star shaped TIPs 203 on a cooling solution 104 according to an embodiment. Each TIP 203 has a plurality of points. In some embodiments, the TIP 203 is surrounded by the neighboring pin interface 101.

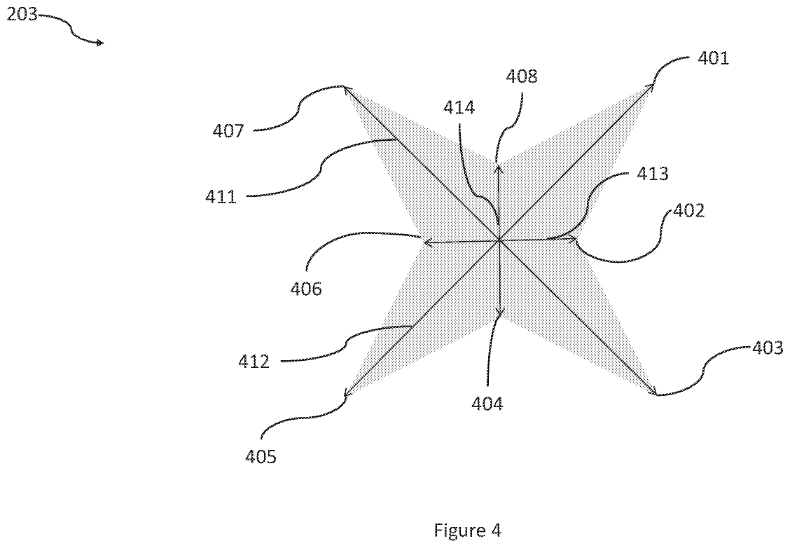

FIG. 4 illustrates further details on the star shaped TIP 203 shown in FIG. 3, according to an embodiment. In some embodiments, the TIP 203 includes a four-point star shape. As shown in FIG. 4, the TIP 203 has a four-point star shape. The four-point star shape includes an upper right point 401, a lower right point 403, an upper left point 407, and a lower left point 405. The embodiments further include an upper point 408, a lower point 404, a left point 406, and a right point 402. The upper point 408 is positioned between the upper left point 407 and the upper right point 401. The left point 406 is positioned between the upper left point 407 and the lower left point 405. The lower point 404 is positioned between the lower left point 405 and the lower right point 403. Left and right diagonal lengths 411, 412, and horizontal and vertical lengths 413, 414 may be determined based on thickness of the TIP 203, the TIM of the TIP, the IC chip 102, and the TIP 203 compression ratio.

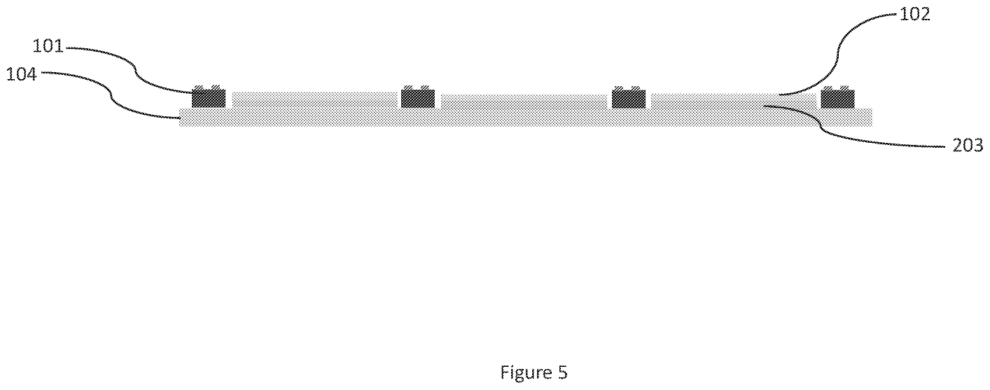

FIG. 5 illustrates a cross-sectional view of embodiments of an IC chip assembly that includes TIPs 203. In some embodiments, the TIP 203 is placed onto the cooling solution 104. Then, the IC chip 102 is mounted onto the TIP 203. In embodiments, pressure is applied to the IC chip 102 and/or the cooling solution 104 to compress the TIP 203. Due to the compression, the TIP 203 is expanded from a star shape into a rectangular shape. The expanded TIP 203 covers most or all the area under the IC chip 102. As shown in FIG. 5, the TIP 203 can fully cover the area under the IC chip 102 and is spaced apart from the neighboring pin interface 101.

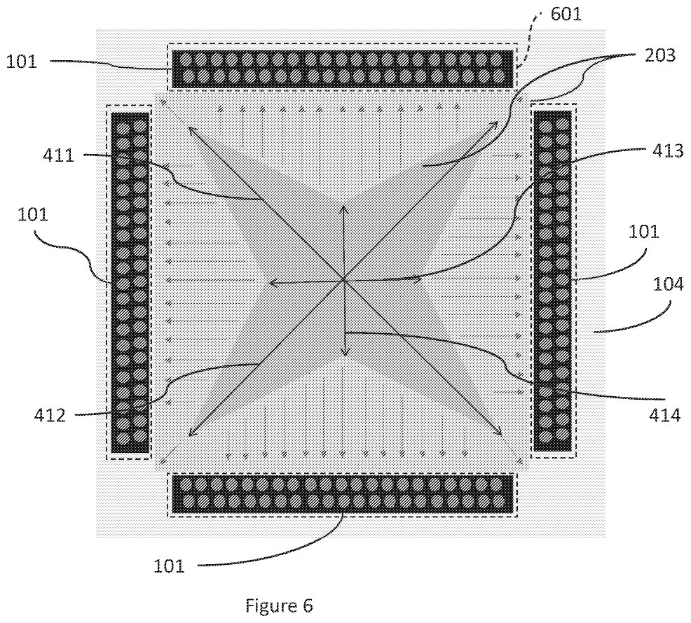

FIG. 6 illustrates the TIP 203 and its expansion due to compression. As illustrated, the TIP 203 has a four-point star shape and expands to a rectangular shape TIP 203. In some embodiments, the expanded TIP 203 fully covers the area under the IC chip 102. In some embodiments, the expanded TIP 203 is larger than the area under the IC chip 102, but the expanded TIP 203 does not expand to neighboring pin interface 101 and/or keep out area 601. The expanded TIP 203 can be outside of a keep out area 601 around the neighboring pin interface 101.

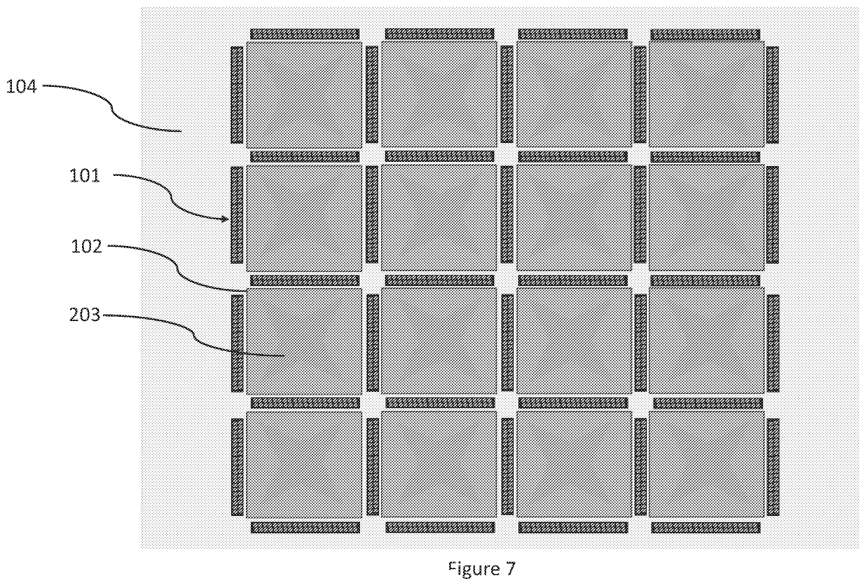

As illustrated in FIG. 7, an array of IC chips 102 can be mounted onto TIPs 203, before the TIPs 203 are compressed. In FIG. 7, the TIPs 203 are positioned under the IC chips 102. The number of IC chips 102 on the cooling solution 104 can be determined based on application. In some embodiments, the cooling solution 104 can have one or more neighboring pin areas interfaces around each of the IC chips 102. In some embodiments, the neighboring pin interface 101 comprises a plurality of pogo pins. In some embodiments, the IC chips 102 are electrically connected to respective pogo pins. The electrical connection can include an electrical wire bonding or via. Through the neighboring pin interface 101, an IC chip 102 can transmit or receive a signal from another IC chip 102. In some embodiments, one or more external devices can be connected to an IC chip 102 through the neighboring pin interface 101.

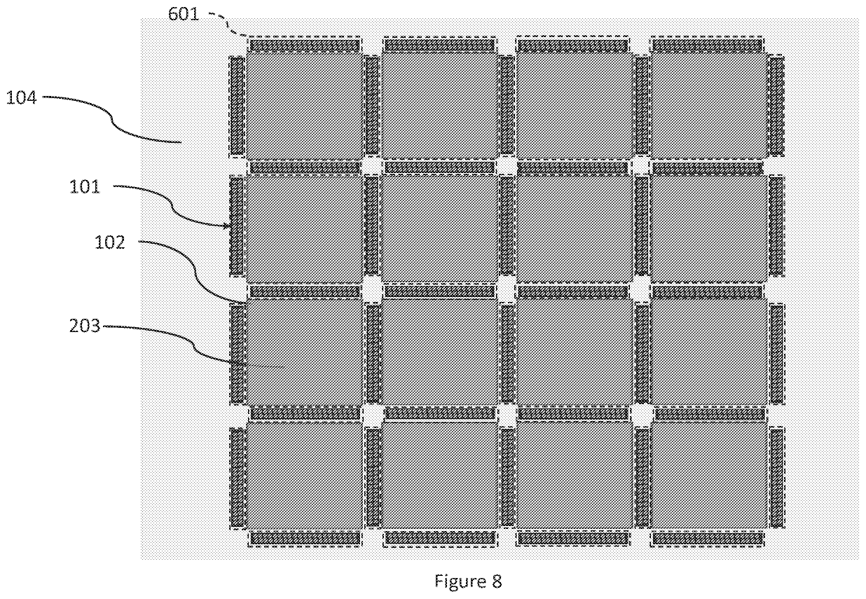

FIG. 8 depicts the array of IC chips 102 of FIG. 7 after the TIPs 203 are compressed. The expanded TIPs 203 can cover most or all of the area under a respective IC chip 102. The expanded TIPs 203 are spaced apart from the respective neighboring pin interfaces 101. The expanded TIPs 203 are also outside of the keep out areas 601 around the pin interfaces 101. This can reduce the chances of the TIPs 203 interfering with pins of the neighboring pin interfaces 101.

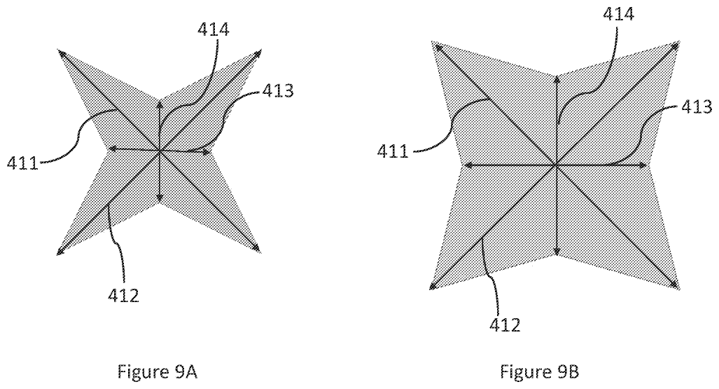

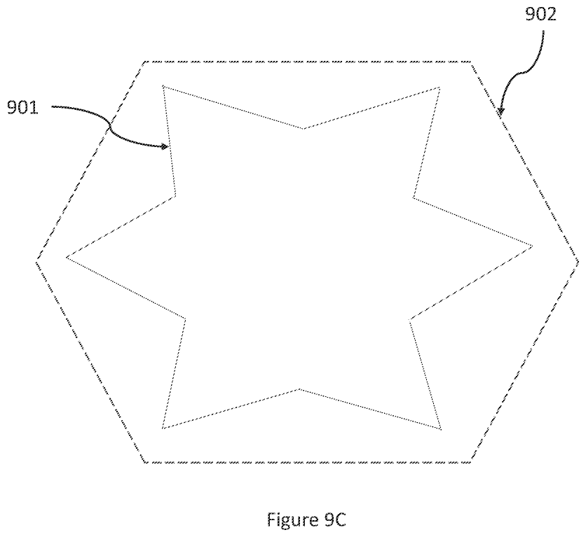

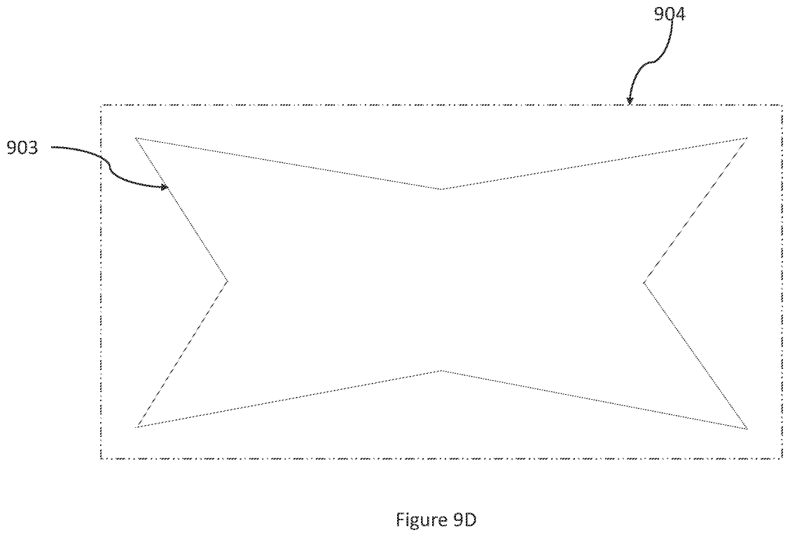

FIGS. 9A and 9B depict embodiments of the TIP 203. These figures illustrate example four points star shapes for TIPs 203. For example, in some embodiments, as shown in FIG. 9A, the left and right diagonal lengths 411, 412 are at least two times longer than the horizontal and vertical lengths 413, 414. For example, in some embodiments, as shown in FIG. 9B, the horizontal and vertical lengths 413, 414 are about 25% shorter than the left and right diagonal lengths 411, 412. The horizontal and vertical lengths 413, 414, and the left and right diagonal lengths 411, 412 may be determined based on the characteristic of IC chip assembly components such as thermal interface material and thickness, compression ratio, IC chip 102, and cooling solution 104. The TIP 203 shape can have various shapes depending on the application. In one embodiment, as shown in FIG. 9C, where a hexagon shape 902 is desirable after its compression, the TIP can have a hexagram shape 901. In another embodiment, as shown in FIG. 9D, where a rectangular shape 904 with a longer horizontal length is desirable after its compression, the TIP can have four point star shape 903, where the vertical length is relatively shorter than the horizontal length 413.

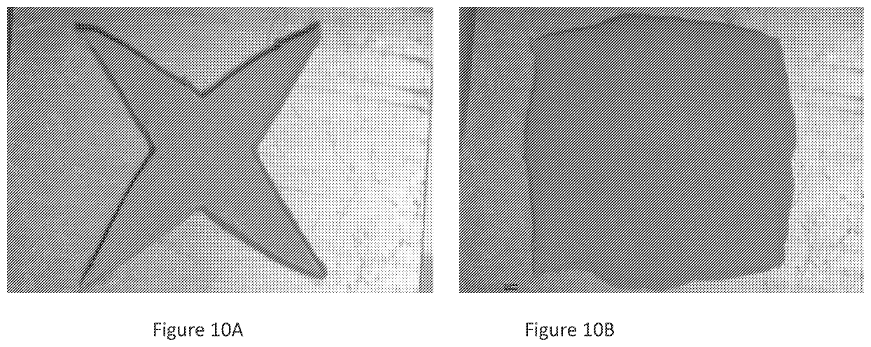

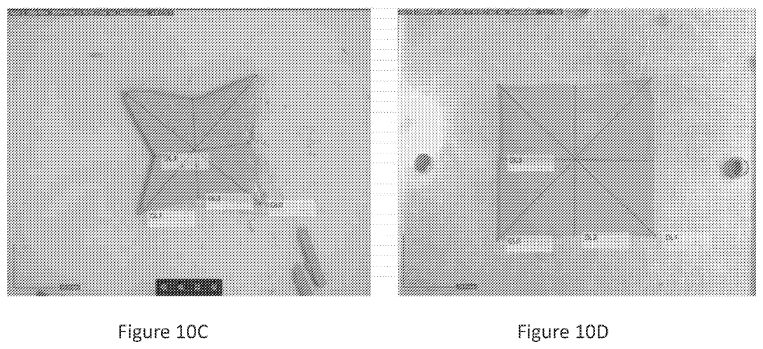

FIGS. 10A to 10D depict example embodiments of the TIP 203 before and after compression. FIGS. 10A and 10C show preferred embodiments of the optimized TIPs 203. Compression during assembly of the star shaped tip of FIG. 10A can result in a generally rectangular TIP after compression as shown in FIG. 10B. Similarly, compression during assembly of the star shaped TIP of FIG. 10C can result in the generally rectangular TIP shown in FIG. 10D. Centers of edges of sides of the rectangular TIP after compression can correspond to points of the star shaped TIP prior to compression. In these embodiments, the TIP expands and changes shape as a result of applied pressure during assembly. FIGS. 10A and 10C show that star shaped TIPs need not be perfectly star shaped. Similarly, FIGS. 10B and 10D show that rectangular shaped TIPs need not be perfectly rectangular shaped.

The shape of TIPs and the number of TIPs disclosed herein are provided illustratively. The disclosed technology is not limited a single TIP being applied to a component. For example, more than one TIP can be applied in a single IC chip. Further, in this example, if the underneath area of IC chip is wide, more than one TIPs can be applied to fully cover the underneath area of the IC chip. In another example, if the underneath area of the IC circuit has a specific shape, such as an L shape, more than one TIP can be arranged to fully cover the L shape of the IC chip. In some instances, components having more complex shapes can be broken down into rectangles and a star shaped TIP can be applied between the component and a cooling solution in each rectangular area of the more complex shape. The example L shaped IC chip can be broken down into two rectangles and two star shaped TIPS can be applied. Compression during manufacture can cause each of the TIPs to expand into rectangular shapes such that TIP material covers substantially the entire area of the component. Furthermore, the neighboring component can be any suitable component where being free from interference by a TIP is desirable.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “may,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

The foregoing description has been described with reference to specific embodiments. However, the illustrative discussions above are not intended to be exhaustive or to limit the inventions to the precise forms described. Many modifications and variations are possible in view of the above teachings. Others skilled in the art are thereby enabled to best utilize the techniques and various embodiments with various modifications as suited to various uses.

Although the disclosure and examples have been described with reference to the accompanying drawings, various changes and modifications will become apparent to those skilled in the art. Such changes and modifications are to be understood as being included within the scope of the disclosure.

1. A method of thermally coupling components in an integrated circuit (IC) assembly, the method comprising:
providing a thermal interface pad between two components in an IC assembly, the thermal interface pad having a star shape with a plurality of points, and connectors are positioned around at least one of the two components; and
applying pressure to at least one of the two components of the IC assembly so as to thermally couple the two components by way of the thermal interface pad, wherein the applying pressure expands the thermal interface pad and changes a shape of the thermal interface pad from the star shape to another shape, and wherein the thermal interface pad is positioned outside of a keep out area around the connectors after the applying pressure.

2. The method of claim 1, wherein the star shape is a four-pointed star shape.

3. The method of claim 1, wherein the shape of the thermal interface pad is rectangular after the applying pressure.

4. The method of claim 1, wherein the two components comprise an integrated circuit chip and a cooling solution.

5. The method of claim 4, wherein the connectors surround the integrated circuit chip.

6. The method of claim 5, wherein the connectors comprise pogo pins.

7. The method of claim 4, wherein the integrated circuit chip is a voltage regulating module.

8. The method of claim 4, further comprising compressing a plurality of additional star shaped thermal interface pads positioned between respective additional integrated circuit chips and the cooling solution.

9. A method of thermally coupling components in an integrated circuit (IC) assembly, the method comprising:
providing a thermal interface pad between two components in an IC assembly; and
applying pressure to at least one of the two components of the IC assembly so as to thermally couple the two components by way of the thermal interface pad, wherein the applying pressure expands the thermal interface pad and changes a shape of the thermal interface pad from a first shape to a rectangular shape, and wherein the thermal interface pad is spaced apart from connector interfaces for connecting to one of the two components after the applying pressure, and wherein the connector interfaces surround the one of the two components.

10. The method of claim 9, wherein the first shape is a star shape.

11. The method of claim 9, wherein the first shape is a four point star shape.

12. The method of claim 9, wherein the first shape is symmetric.

13. The method of claim 9, wherein the rectangular shape of the thermal interface pad is outside of keep out areas around the connector interfaces areas-after the applying pressure.

14. The method of claim 13, wherein each of the connector interfaces include a plurality of pogo pins.

15. The method of claim 13, wherein the two components comprise an integrated circuit chip and a cooling solution.

16. The method of claim 15, wherein the integrated circuit chip is a voltage regulating module.

17. An electronic assembly made by a process, the process comprising:
providing a thermal interface pad between an integrated circuit chip and a cooling solution, the thermal interface pad having a star shape with a plurality of points; and
applying pressure so as to thermally couple the integrated circuit chip to the cooling solution by way of the thermal interface pad, wherein the applying pressure expands the thermal interface pad and changes the shape of the thermal interface pad from the star shape to a rectangular shape, and wherein the rectangular shape of the thermal interface pad is positioned outside of keep out regions surrounding the integrated circuit chip.

18. The electronic assembly of claim 17, further comprising connector interfaces around the integrated circuit chip, wherein the keep out regions are around the connector interfaces.

19. The electronic assembly of claim 17, wherein the integrated circuit chip comprises a voltage regulating module.

20. The electronic assembly of claim 17, wherein the cooling solution comprises a cold plate.
